(19) United States
(12) Patent Application Publication
(10) Pub. No.: US 2025/0261399 A1
(43) Pub. Date: Aug. 14, 2025

(54) SEMICONDUCTOR DEVICE

(71) Applicant: FUJI ELECTRIC CO., LTD., Kawasaki-shi (JP)

(72) Inventor: Syunki NARITA, Matsumoto-city (JP)

(73) Assignee: FUJI ELECTRIC CO., LTD., Kawasaki-shi (JP)

(21) Appl. No.: 19/004,091

(22) Filed: Dec. 27, 2024

(30) Foreign Application Priority Data
Feb. 8, 2024 (JP) 2024-018213

(51) Int. Cl. H10D 30/66; H10D 62/10; H10D 62/832

(52) U.S. Cl. CPC H10D 30/665; H10D 62/106; H10D 62/8325

(57) ABSTRACT

A semiconductor device, including: a semiconductor substrate of a first conductivity type, the semiconductor substrate having an active region through which a main current flows, a termination region surrounding a periphery of the active region in a plan view of the semiconductor device, and a transition region between the active region and the termination region; a plurality of first semiconductor regions of a second conductivity type, formed in the semiconductor substrate; a front electrode at a surface of the semiconductor substrate, in the active region, the front electrode being connected to the plurality of first semiconductor regions; a source ring for pulling out a current, the source ring being electrically connected to the front electrode in the transition region, and having a side facing the semiconductor substrate; and a second semiconductor region of the first conductivity type, formed in the semiconductor substrate at the side of the source ring, the source ring being connected to the second semiconductor region.

### CROSS REFERENCE TO RELATED APPLICATIONS

This application is based upon and claims the benefit of priority of the prior Japanese Patent Application No. 2024-018213, filed on Feb. 8, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

In a known semiconductor device, a first well region formed in a drift layer at a top surface of the drift layer; a gate electrode; a second well region bordering the first well region in a plan view; an interlayer insulating film; and a gate portion that covers the gate electrode exposed from the interlayer insulating film are provided to reduce adverse effects on a surface electrode of the semiconductor device; and an outer end of the gate electrode is farther from the first well region than is an outer end of the gate portion but closer to the first well region than is an outer end of the second well region (for example, refer to International Publication No. WO 2021/245992).

### SUMMARY OF THE INVENTION

According to an embodiment of the present disclosure, a semiconductor device includes: a semiconductor substrate of a first conductivity type, the semiconductor substrate having: an active region through which a main current flows, a termination region surrounding a periphery of the active region in a plan view of the semiconductor device, and a transition region between the active region and the termination region; a plurality of first semiconductor regions of a second conductivity type, formed in the semiconductor substrate; a front electrode at a surface of the semiconductor substrate, in the active region, the front electrode being connected to the plurality of first semiconductor regions; a source ring for pulling out a current, the source ring being electrically connected to the front electrode in the transition region, and having a side facing the semiconductor substrate; and a second semiconductor region of the first conductivity type, formed in the semiconductor substrate at the side of the source ring, the source ring being connected to the second semiconductor region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a top view depicting a structure of a silicon carbide semiconductor device according to a first embodiment.

FIG. 2 is a cross-sectional view depicting the structure of the silicon carbide semiconductor device according to the first embodiment along cutting line Y-Y′ depicted in FIG. 1.

FIG. 3 is a cross-sectional view depicting the structure of the silicon carbide semiconductor device according to the first embodiment along cutting line X-X′ depicted in FIG. 1.

FIG. 4 is a top view depicting a structure of a silicon carbide semiconductor device according to a second embodiment.

FIG. 5 is a cross-sectional view depicting the structure of the silicon carbide semiconductor device according to the second embodiment along cutting line Y-Y′ depicted in FIG. 4.

FIG. 6 is a top view depicting a structure of a silicon carbide semiconductor device according to a third embodiment.

FIG. 7 is a cross-sectional view depicting the structure of the silicon carbide semiconductor device according to the third embodiment along cutting line Y-Y′ depicted in FIG. 6.

FIG. 8 is a cross-sectional view depicting a structure of a silicon carbide semiconductor device according to a fourth embodiment along cutting line Y-Y′ depicted in FIG. 6.

FIG. 9 is a cross-sectional view depicting current distribution of the conventional silicon carbide semiconductor device.

FIG. 10 is a cross-sectional view depicting current distribution of the silicon carbide semiconductor device according to the first embodiment.

FIG. 11 is a cross-sectional view depicting a structure of a conventional silicon carbide semiconductor device.

FIG. 12 is a cross-sectional view depicting the structure of the conventional silicon carbide semiconductor device.

FIG. 13 is a top view depicting the structure of the conventional silicon carbide semiconductor device.

FIG. 14 is a top view of electrodes of the conventional silicon carbide semiconductor device.

### DETAILED DESCRIPTION OF THE INVENTION

First, problems associated with the conventional techniques are discussed. In a conventional semiconductor device, a problem occurs in that during rated forward surge current (IFSM) testing, current concentrates at a source ring portion and IFSM capability decreases.

An outline of an embodiment of the present disclosure is described. A semiconductor device according to the present disclosure solving the problems above has the following features. The semiconductor device has a semiconductor substrate of a first conductivity type, the semiconductor substrate having an active region through which a main current flows, a termination region surrounding a periphery of the active region, and a transition region between the active region and the termination region. The semiconductor device further has a front electrode at a surface of the semiconductor substrate, in the active region, the front electrode being connected to a plurality of first semiconductor regions of a second conductivity type; a source ring for pulling out a current and electrically connected to the front electrode in the transition region, the source ring having a side facing the semiconductor substrate; a second semiconductor region of the first conductivity type, provided at the side of the source ring.

According to the disclosure described above, beneath the source ring is the second semiconductor region of the first conductivity type, whereby a flow of current from the plurality of first semiconductor regions of the second conductivity type to the source ring is enabled while a flow of current from the source ring to the plurality of first semiconductor regions is prevented. Thus, even when resistance increases due to increases in temperature during IFSM testing, the flow of current from the source ring to the plurality of first semiconductor regions may be prevented, concentration of the current in a source ring connecting portion is prevented, and IFSM capability may be improved.

Further, in the semiconductor device according to the present disclosure, in the described disclosure above, the second semiconductor region is one of a plurality of second semiconductor regions provided in the active region, the termination region, and the transition region, the second semiconductor region being provided in an entire area of the surface of the semiconductor substrate in the transition region.

Further, in the semiconductor device according to the present disclosure, in the described disclosure above, the plurality of first semiconductor regions is provided in the termination region and the transition region; the second semiconductor region is provided at the side of the source ring, in the transition region; and the second semiconductor region is one of a plurality of second semiconductor regions provided in the termination region and the transition region, the plurality of second semiconductor regions being in contact with the plurality of first semiconductor regions in the termination region and in the transition region.

Further, in the semiconductor device according to the present disclosure, in the described disclosure above, the plurality of first semiconductor regions is provided in the active region, the termination region, and the transition region; and the second semiconductor region is in contact with the plurality of first semiconductor regions in the transition region and is provided at the side of the source ring in the transition region.

According to the disclosure described above, a width of the second semiconductor region of the first conductivity type is narrow, whereby Vf (forward voltage) may be lowered.

Further, the semiconductor device according to the present disclosure, in the described disclosure above, further includes a third semiconductor region of the second conductivity type, facing the plurality of first semiconductor regions in a depth direction, the third semiconductor region having a dopant concentration higher than a dopant concentration of the plurality of first semiconductor regions; and the second semiconductor region is deeper than the plurality of first semiconductor regions and reaches the third semiconductor region in the depth direction.

According to the disclosure described above, the second semiconductor region of the first conductivity type is formed deeply, whereby a difference in n-type and p-type concentrations is small, and imbalance of the n-type and p-type concentrations during application of reverse bias may be suppressed.

Further, in the semiconductor device according to the present disclosure, in the described disclosure above, a dopant concentration of the plurality of first semiconductor regions is higher than a dopant concentration of the second semiconductor region.

Findings underlying the present disclosure are discussed. First, problems associated with the conventional semiconductor device are discussed. In terms of power semiconductor devices, semiconductor materials to replace silicon are being investigated, and silicon carbide (SiC) is attracting attention as a semiconductor material that enables fabrication (manufacturing) of next-generation power semiconductor devices that have excellent low on-voltage, high-speed characteristics, and high-temperature characteristics.

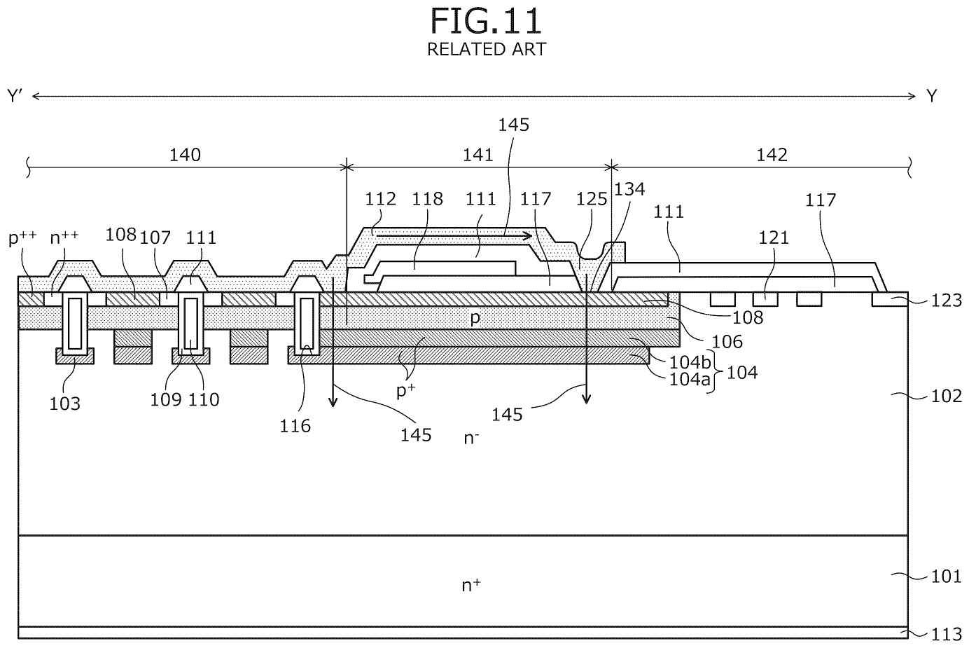

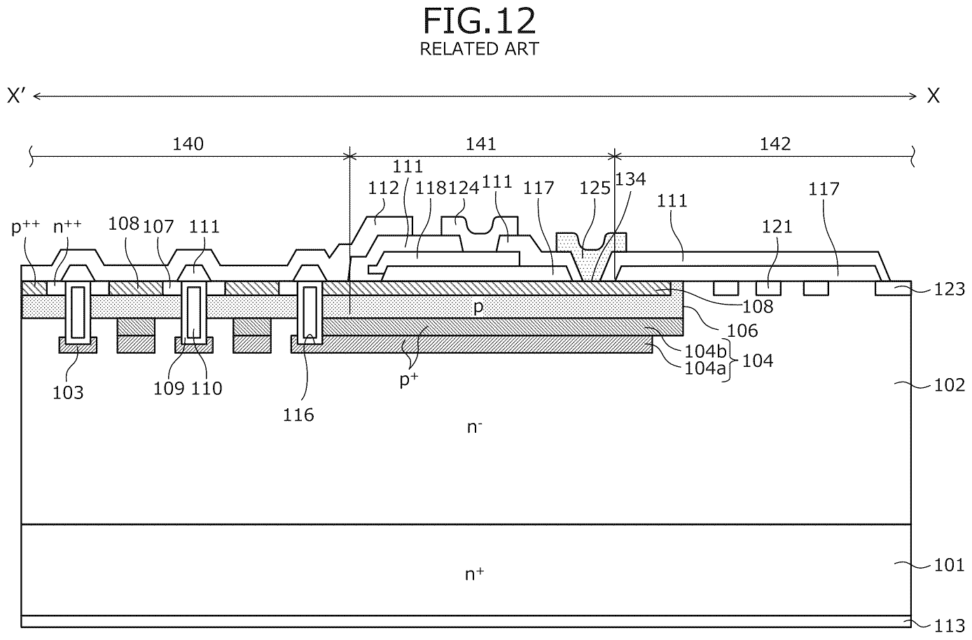

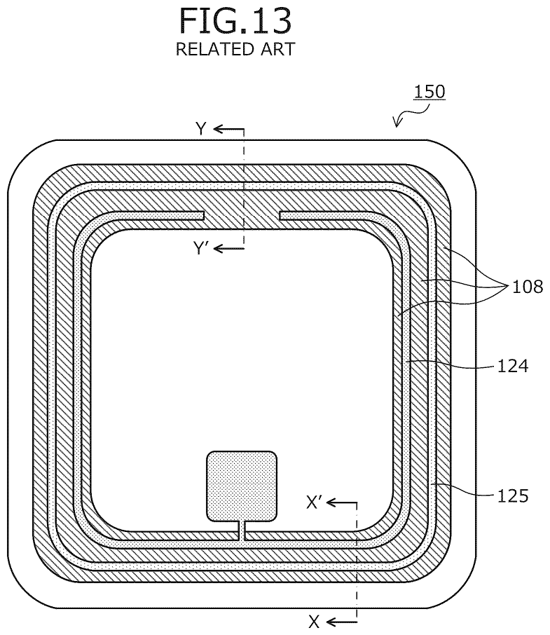

FIGS. 11 and 12 are cross-sectional views depicting a structure of a conventional silicon carbide semiconductor device. FIG. 11 is a cross-sectional view along cutting line Y-Y′ depicted in FIG. 13 while FIG. 12 is a cross-sectional view along cutting line X-X′ depicted in FIG. 13. In FIGS. 11 and 12, a trench-type MOSFET 150 is depicted as the conventional silicon carbide semiconductor device.

As depicted in FIGS. 11 and 12, the trench-type MOSFET 150 has a MOS gate with a general trench gate structure provided in an active region 140 of a semiconductor substrate that contains silicon carbide (hereinafter, silicon carbide substrate), the MOS gate being provided in the semiconductor substrate, at a front surface thereof (surface having a later-described p-type base layer 106). The silicon carbide substrate (semiconductor chip) is formed by sequentially growing silicon carbide layers by epitaxy on an n⁺-type starting substrate (hereinafter, n⁺-type silicon carbide substrate) 101 that contains silicon carbide; the silicon carbide layers constitute an n⁻-type drift layer 102 and a p-type base layer 106, respectively. Hereinafter, the n⁺-type starting substrate 101, the n⁻-type drift layer 102, and the p-type base layer 106 are collectively referred to as a silicon carbide semiconductor substrate.

At a front surface (surface facing the n⁻-type drift layer 102) of the n⁺-type starting substrate 101, MOS gate structures configured by the p-type base layer 106, n⁺⁺-type source regions 107, trenches 116, gate insulating films 109, and gate electrodes 110 are provided. Further, reference numerals 108, 111, and 112 are p⁺⁺-type contact regions, an interlayer insulating film, and a source electrode, respectively. A back electrode 113 constituting a drain electrode is provided at a back surface of the n⁺-type starting substrate 101.

In the n⁻-type drift layer 102, at a front surface thereof, second p⁺-type base regions 104 configured by first p⁺-type regions 104a and second p⁺-type regions 104b are selectively provided between the trenches 116. Further, in the n⁻-type drift layer 102, first p⁺-type base regions 103 are selectively provided so as to border an entire bottom of each of the trenches 116.

Further, as depicted in FIGS. 11 and 12, the trench-type MOSFET 150 has the active region 140 through which current flows, when a device structure is formed and is in an on-state; a termination structure region 142 that surrounds a periphery of the active region 140 in a plan view and sustains a breakdown voltage; and a transition region 141 between the active region 140 and the termination structure region 142.

In the termination structure region 142, the p-type base layer 106, the p⁺⁺-type contact regions 108, and the second p⁺-type base regions 104 are partially provided while in a portion of the termination structure region 142 free of the p-type base layer 106, the p⁺⁺-type contact regions 108, and the second p⁺-type base regions 104: the n⁻-type drift layer 102 is exposed and at the surface of the n⁻-type drift layer 102, a voltage withstand structure such as a junction termination extension (JTE) structure, a guard ring structure 121, etc. is provided.

The guard ring structure 121 is constituted by p-type regions that have different dopant concentrations and, in a plan view, have a substantially rectangular shape surrounding the periphery of the active region 140 and are disposed in descending order of dopant concentration in a direction from the active region 140 side (center of the n⁺-type starting substrate 101) to the outside (end of the n⁺-type starting substrate 101). Additionally, closer to the end of the n⁺-type starting substrate 101 than is the voltage withstand structure, an n⁺⁺-type region 123 constituting a channel stopper is disposed. An initial oxide film 117 and the interlayer insulating film 111 are provided at the surfaces of the voltage withstand structure and the n⁺⁺-type region 123, and a protective film (not depicted) containing a polyimide or the like is provided at a surface of the trench-type MOSFET 150.

The energy level of p-type dopants is deep in SiC and thus, resistance in a p-type region is high, especially at low temperatures such as −40 degrees C. or −55 degrees C. Thus, when dV/dt is applied to the device, lateral voltage drop due to hole current flowing in the p-type region is large, and a large voltage is applied between the p-type region and an electrode provided on the p-type region via the insulating film, resulting in a defect in which the insulating film is destroyed. This phenomenon tends to occur in a vicinity of the active region, where current from a non-active region such as the voltage withstand structure concentrates. To solve this problem, a source ring 125 that pulls out the hole current in the vicinity of the active region 140 and flows the hole current through the source electrode 112 is conventionally provided.

As depicted in FIGS. 11 and 12, in the transition region 141, the initial oxide film 117 and the interlayer insulating film 111 are provided at a front surface of the p⁺⁺-type contact region 108 in the transition region 141; the source ring 125 is embedded in openings of the initial oxide film 117 and the interlayer insulating film 111; and a silicide layer 134 of the source ring 125 is in ohmic contact with the p⁺⁺-type contact region 108. The source ring 125 is electrically connected to the source electrode 112. This configuration enables the hole current in the vicinity of the active region to be pulled out by the source ring 125 and flowed through the source electrode 112.

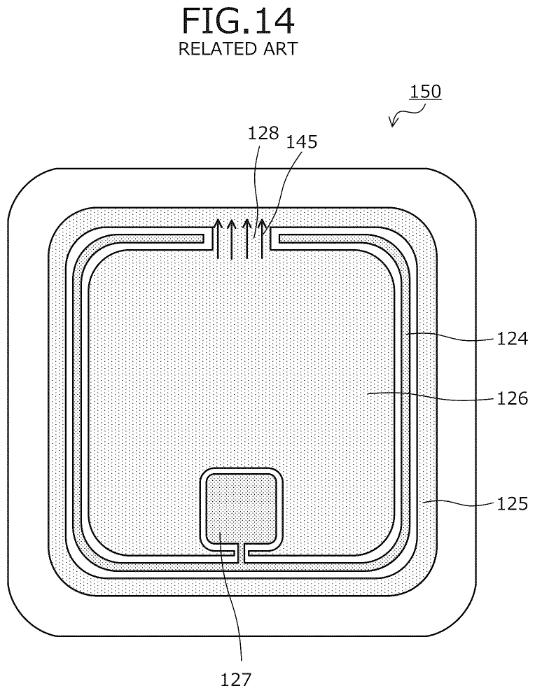

Further, as depicted in FIG. 12, in the transition region 141, a gate ring 124 for connecting the gate electrodes 110 to a gate electrode pad 127 (refer to FIG. 14) is provided. In the transition region 141, to insulate the p⁺⁺-type contact region 108 therein, the initial oxide film 117 is provided and a polysilicon 118 connected to the gate electrodes 110 is provided on the initial oxide film 117. The gate ring 124 is connected to the polysilicon 118 by an opening provided in the interlayer insulating film 111.

FIG. 13 is a plan view depicting the gate ring 124, the source ring 125, and the p⁺⁺-type contact regions 108 of the conventional silicon carbide semiconductor device. As depicted in FIG. 13, one of the p⁺⁺-type contact regions 108 is provided beneath the gate ring 124 and the source ring 125.

FIG. 14 is a plan view of electrodes of the conventional silicon carbide semiconductor device. As depicted in FIG. 14, at a top surface of the trench-type MOSFET 150, a source electrode pad 126 connected to the source electrode 112 (refer to FIGS. 11 and 12) and a gate electrode pad 127 connected to the gate electrodes 110 (refer to FIGS. 11 and 12) via the gate ring 124 are provided. The gate ring 124 is formed in a substantially rectangular shape surrounding a periphery of the source electrode pad 126 in a plan view. The source ring 125 is connected to the source electrode 112 in a source ring connecting portion 128. The source ring connecting portion 128 may be provided in plural.

In silicon carbide semiconductor device in which the source ring 125 is provided, a problem arises in that when resistance increases due to increases in temperature during an IFSM test, a current 145 flows from the source ring 125 to the p⁺⁺-type contact region 108 and, as depicted in FIG. 14, the current 145 concentrates in the source ring connecting portion 128 whereby the IFSM capability decreases.

Embodiments of a semiconductor device according to the present disclosure solving the problems of the conventional semiconductor device described above are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or − . In the description of the embodiments beneath and the accompanying drawings, main portions that are identical are given the same reference numerals and are not repeatedly described. Further, with consideration of variation in manufacturing, description indicating the same or equal may be within 5%.

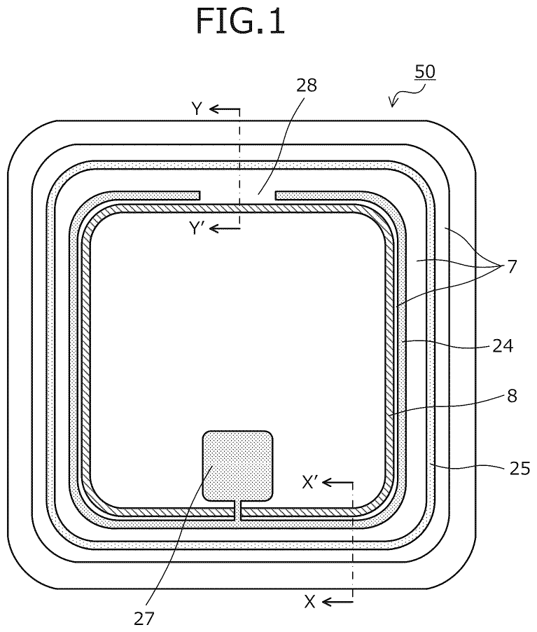

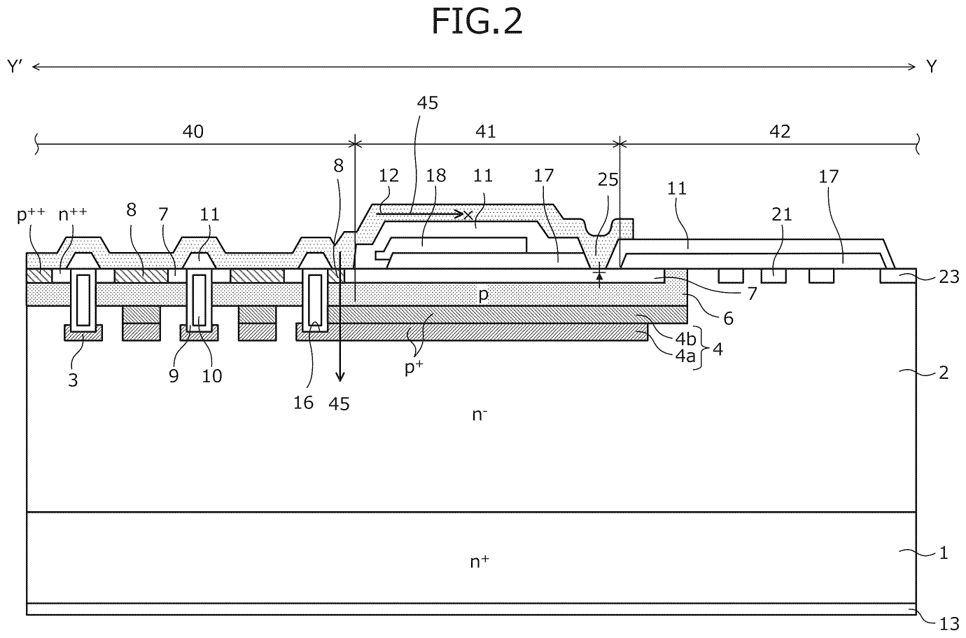

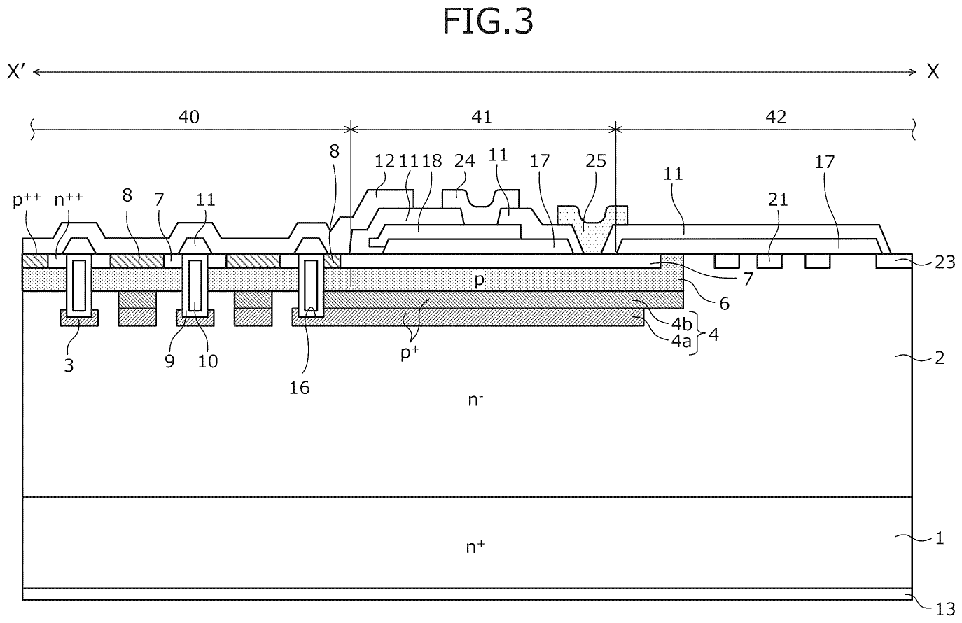

A semiconductor device according to the present disclosure contains a wide band gap semiconductor. In a first embodiment, a silicon carbide semiconductor device fabricated (manufactured) using, for example, silicon carbide (SiC) as a wide band gap is described taking a trench-type MOSFET 50 as an example. FIG. 1 is a plan view depicting a gate ring 24, a source ring 25, one of multiple p⁺⁺-type contact regions 8, and n⁺⁺-type source regions 7 of the silicon carbide semiconductor device according to the first embodiment. FIG. 2 is a cross-sectional view depicting a structure of the silicon carbide semiconductor device according to the first embodiment along cutting line Y-Y′ depicted in FIG. 1. FIG. 3 is a cross-sectional view depicting the structure of the silicon carbide semiconductor device according to the first embodiment along cutting line X-X′ depicted in FIG. 1.

As depicted in FIGS. 1 to 3, the trench-type MOSFET 50 according to the first embodiment includes an active region 40 in which a device structure is formed and through which a current flows during an on-state, a termination structure region 42 surrounding a periphery of the active region 40 in a plan view and sustaining a breakdown voltage, and a transition region 41 between the active region 40 and the termination structure region 42. Further, in the trench-type MOSFET 50, an n⁻-type drift layer 2 is deposited on a first main surface (front surface), for example, a (0001) plane, (Si-face), of an n⁺-type starting substrate (semiconductor substrate of a first conductivity type) 1.

The n⁺-type starting substrate 1 is a silicon carbide single crystal substrate. The n⁻-type drift layer 2, for example, is a low-concentration n-type drift layer having a dopant concentration lower than a dopant concentration of the n⁺-type starting substrate 1. At a first surface of the n⁻-type drift layer (semiconductor substrate of the first conductivity type) 2, opposite to a second surface thereof facing the n⁺-type starting substrate 1, an n-type high-concentration region (not depicted) may be provided. The n-type high-concentration region is a high-concentration n-type layer having a dopant concentration lower than the dopant concentration of the n⁺-type starting substrate 1 but higher than the dopant concentration of the n⁻-type drift layer 2.

At the first surface of the n⁻-type drift layer 2 (in an instance in which the n-type high-concentration region is provided, at a first surface of the n-type high-concentration region), a p-type base layer (first semiconductor region of a second conductivity type) 6 is provided. Hereinafter, the n⁺-type starting substrate 1, the n⁻-type drift layer 2, and the p-type base layer 6 are collectively referred to as a silicon carbide semiconductor substrate. In the p-type base layer 6, the n⁺⁺-type source regions (second semiconductor regions of the first conductivity type) 7 and the p⁺⁺-type contact regions (first semiconductor regions of the second conductivity type) 8 are selectively provided.

A back electrode 13 constituting a drain electrode is provided at a second main surface (back surface, i.e., back surface of the silicon carbide semiconductor substrate) of the n⁺-type starting substrate 1.

In the silicon carbide semiconductor substrate, at a first main surface (surface having the p-type base layer 6) thereof, a trench structure is formed. In particular, from a first surface (the first main surface of the silicon carbide semiconductor substrate) of the p-type base layer 6, opposite to a second surface thereof facing the n⁺-type starting substrate 1, trenches 16 penetrate through the p-type base layer 6 and reach the n⁻-type drift layer 2. Further, each of the trenches 16 is provided in a stripe-like shape. Along respective inner walls of the trenches 16, a gate insulating film 9 is formed at bottoms and sidewalls of the trenches 16 and gate electrodes 10 are formed on the gate insulating film 9 in the trenches 16. The gate insulating film 9 insulates the gate electrodes 10 from the n⁻-type drift layer 2 and the p-type base layer 6. A portion of each of the gate electrodes 10 may protrude from a top (side facing a later-described source electrode 12) of each of the trenches 16 in a direction to the source electrode 12.

In the n⁻-type drift layer 2, closer to the first surface (surface facing the first main surface of the silicon carbide semiconductor substrate) thereof than to the second surface thereof facing the n⁺-type starting substrate 1, second p⁺-type base regions (third semiconductor regions of the second conductivity type) 4 are selectively provided. The second p⁺-type base regions 4 are provided in at least a surface layer of the n⁻-type drift layer 2, at the first surface thereof. The second p⁺-type base regions 4 are apart from the trenches 16 and reach deeper positions closer to the n⁺-type starting substrate 1 than are the bottoms of the trenches 16. The second p⁺-type base regions 4 are configured by first p⁺-type regions 4a of a same thickness as a thickness of first p⁺-type base regions 3 described hereinafter, and second p⁺-type regions 4b provided at surfaces of the first p⁺-type regions 4a., respectively.

The first p⁺-type base regions 3 are provided at positions facing the bottoms of the trenches 16 in a depth direction. A width of each of the first p⁺-type base regions 3 is a same as or wider than a width of each of the trenches 16. The bottoms of the trenches 16 may reach the first p⁺-type base regions 3 or may terminate in the n⁻-type drift layer 2, between the p-type base layer 6 and the first p⁺-type base regions 3. The first p⁺-type base regions 3 and the second p⁺-type base regions 4 are doped with, for example, aluminum (Al).

The first p⁺-type base regions 3 form a structure in which the first p⁺-type base regions 3 are connected to the second p⁺-type base regions 4 by portions of each of the first p⁺-type base regions 3 being extended toward the trenches 16. The first p⁺-type regions 4a of the second p⁺-type base regions 4 are closer to the n⁺-type starting substrate 1 than are the bottoms of the trenches 16 and partially extend to be connected to the first p⁺-type base regions 3. Further, the second p⁺-type regions 4b of the second p⁺-type base regions 4 are closer to the source electrode 12 than are the bottoms of the trenches 16 and may partially extend. FIGS. 2 and 3 depict locations where the first p⁺-type base regions 3 and the second p⁺-type base regions 4 are apart from each other. In portions of the active region 40 and the transition region 41, the p-type base layer 6 is provided so as to cover the second p⁺-type regions 4b and the n−-type drift layer 2.

Further, of the trenches 16 of the active region 40, an outermost one closest to the transition region 41 has an outer sidewall facing the transition region 41, the outer sidewall being in contact with one of the p⁺⁺-type contact regions 8, one of the first p⁺-type regions 4a, and one of the second p⁺-type regions 4b; said one of the second p⁺-type regions 4b is in contact with one of the first p⁺-type base regions 3. Thus, this outer sidewall (sidewall facing the transition region 41) of the outermost one of the trenches 16 is not in contact with the n⁻-type drift layer.

An interlayer insulating film 11 is provided in an entire area of the front surface of the silicon carbide substrate, so as to cover the gate electrodes 10 embedded in the trenches 16. The source electrode (front electrode) 12 is in ohmic contact with the n⁺⁺-type source regions 7 and the p⁺⁺-type contact regions 8 via contact holes opened in the interlayer insulating film 11. The source electrode 12 is electrically insulated from the gate electrodes 10 by the interlayer insulating film 11. A source electrode pad (not depicted) is provided on the source electrode 12. The source electrode 12 and the source electrode pad may be a single layer or may be stacked layers of different materials.

In FIGS. 2 and 3, while three trench MOS structures are depicted in the active region 40, further trench MOS (metal-oxide-semiconductor insulated gate) structures may be disposed in parallel.

Further, in the transition region 41, the gate ring 24 for connecting the gate electrodes 10 to a gate electrode pad 27 is formed in a substantially rectangular shape surrounding the periphery of the active region 40 in a plan view. In the transition region 41, an initial oxide film 17 functioning as a field oxide film is provided above the p⁺⁺-type contact region 8 in the transition region 41 to insulate the p⁺⁺-type contact region 8. The gate insulating film 9 is provided on the initial oxide film 17 and a polysilicon 18 connected to the gate electrodes 10 is provided on the gate insulating film 9. The gate ring 24 is connected to the polysilicon 18 by an opening provided in the interlayer insulating film 11.

Further, in the transition region 41, the source ring 25 for pulling out charge is formed in a substantially rectangular shape surrounding a periphery of the gate ring 24 in a plan view. The source ring 25 is connected to the source electrode 12 in a source ring connecting portion 28. The source ring connecting portion 28 may be provided in plural. The source ring 25 is connected to an outermost one of the n⁺⁺-type source regions 7 by openings provided, respectively, in the interlayer insulating film 11, the gate insulating film 9, and the initial oxide film 17, the outermost one of the n⁺⁺-type source regions 7 being closest to the end of the n⁺-type starting substrate 1, of the n⁺⁺-type source regions 7. As a result, the source ring 25 may lead current generated in the transition region 41 out to the source electrode 12.

Further, the termination structure region 42 is free of the p-type base layer 6 and the n-type high-concentration region; the n⁻-type drift layer 2 is exposed in the termination structure region 42; and a voltage withstand structure such as junction termination extension (JTE) structure, a guard ring structure 21, etc. is provided in the n⁻-type drift layer 2, at the first surface of the n⁻-type drift layer 2.

The guard ring structure 21 is constituted by interspersed p-type regions that progressively reduce the dopant concentration of the guard ring structure 21 in a direction from the transition region 41 to the end of the n⁺-type starting substrate 1, said p-type regions each being disposed in a substantially rectangular shape surrounding the peripheries of the active region 40 and the transition region 41 in a plan view. Further, instead of varying the dopant concentration of said p-type regions, said p-type regions may be disposed so that an interval therebetween is relatively larger the closer said p-type regions are to the end of the n⁺-type starting substrate 1 or said p-type regions may be of different widths and may be disposed in descending order of width in a direction from the transition region 41 to the end of the n⁺-type starting substrate 1. In an instance of a JTE structure, contiguous p-type regions arranged in descending order of dopant concentration in a direction from the transition region 41 to the end of the n⁺-type starting substrate 1 are each disposed in a substantially rectangular shape surrounding the peripheries of the active region 40 and the transition region 41 in a plan view. Closer to the end of the n⁺-type starting substrate 1 than are these voltage withstand structures, an n⁺⁺-type region 23 constituting a channel stopper is disposed. The interlayer insulating film 11, the gate insulating film 9, and the initial oxide film 17 are provided at the surfaces of voltage withstand structures and the n⁺⁺-type region 23, and a protective film (not depicted) constituted by a polyimide or the like is provided at a top surface of the trench-type MOSFET 50.

Here, a boundary between the active region 40 and the transition region 41 is a bottom of steps of the gate insulating film 9 and the interlayer insulating film 11 on the outermost one of the n⁺⁺-type source regions 7 while a boundary between the transition region 41 and the termination structure region 42 is a bottom of a step of the initial oxide film 17.

Further, the n⁺⁺-type source regions 7, the p-type base layer 6, and the second p⁺-type base regions 4 extend to the termination structure region 42, and the voltage withstand structure is provided outside of these regions. The n⁺⁺-type source regions 7 are shorter than the p-type base layer 6, and a portion of the p-type base layer 6 is exposed at the surface of the silicon carbide substrate. In the transition region 41 and the termination structure region 42, in the second p⁺-type base region 4 thereof, the first p⁺-type region 4a is shorter than the second p⁺-type region 4b, which has a same length as a length of a portion of the p-type base layer 6.

As depicted in FIG. 1, in the first embodiment, all the p⁺⁺-type contact regions 8 are provided closer to a center of the active region 40 than is the gate ring 24 in a plan view; the n⁺⁺-type source regions 7 are provided closer to the end of the n⁺-type starting substrate 1 than are the p⁺⁺-type contact regions 8; and the outermost one of the n⁺⁺-type source regions 7 is provided beneath the gate ring 24 and the source ring 25 (is provided at sides that face the n⁺-type starting substrate 1).

Further, as depicted in FIGS. 2 and 3, in the first embodiment, while the p⁺⁺-type contact regions 8 are not provided in the transition region 41 or the termination structure region 42, one of the p⁺⁺-type contact regions 8 is provided in a portion in contact with the outer sidewall of the outermost one of the trenches 16, the outermost one of the trenches 16 being in the active region 40 and closest to the transition region 41, of the trenches 16. The n⁺⁺-type source regions 7 are in contact with the p⁺⁺-type contact regions 8 and are provided to the termination structure region 42, the n⁺⁺-type source regions 7 being provided on sides of the p⁺⁺-type contact regions 8, said sides facing the end of the n⁺-type starting substrate 1. Thus, the source ring 25 is in contact with the outermost one of the n⁺⁺-type source regions 7 by an opening in the interlayer insulating film 11 and is not in contact with the p⁺⁺-type contact regions 8.

As described, a diode formed by the outermost one of the n⁺⁺-type source regions 7 and the p-type base layer 6 is formed beneath the source ring 25. As a result, a flow of current from the p-type base layer 6 to the source ring 25 is enabled while a flow of current from the source ring 25 to the p-type base layer 6 may be prevented. Thus, even when resistance increases due to increases in temperature during an IFSM test, the flow of a current 45 from the source ring 25 to the p⁺⁺-type contact regions 8 may be prevented, concentration of the current 45 in the source ring connecting portion 28 is prevented, and IFSM capability may be improved.

A method of manufacturing the silicon carbide semiconductor device according to the first embodiment may be implemented as follows. Here, an instance of a MOSFET of a 1200V breakdown voltage class being manufactured is described. First, the n⁺-type starting substrate (semiconductor wafer) 1 containing single crystal silicon carbide and doped with an n-type impurity (dopant) such as nitrogen (N) so as to have a dopant concentration of, for example, 2.0×10¹⁹/cm³ is prepared. The front surface of the n⁺-type starting substrate 1 may be, for example, a (0001) plane having an off-angle of about 4degrees in a <11-20>direction. Next, the n⁻-type drift layer 2 doped with an n-type dopant such as nitrogen to have a dopant concentration of, for example, 1.0×10¹⁶/cm³, is grown by epitaxy on the front surface of the n⁺-type starting substrate 1 to a thickness of, for example, 10 μm.

Next, in the n⁻-type drift layer 2, at the surface thereof, the n-type high-concentration region may be selectively formed by photolithography and ion implantation. In this ion implantation, an n-type impurity (dopant) such as nitrogen may be implanted so as to have a concentration of, for example, 1×10¹⁷/cm³.

Next, the first p⁺-type base regions 3 and the first p⁺-type regions 4a are selectively formed in the n⁻-type drift layer 2 by photolithography and ion implantation. Next, in the n⁻-type drift layer 2, at the surface thereof, the second p⁺-type regions 4b are selectively formed. In this ion implantation, for example, a p-type impurity (dopant) such as aluminum (Al) may be ion implanted in the first p⁺-type base regions 3, the first p⁺-type regions 4a, and the second p⁺-type regions 4b so that a dopant concentration thereof is 5.0×10¹⁸/cm³.

Next, at the surface of the n⁻-type drift layer 2, the p-type base layer 6 doped with a p-type dopant such as aluminum to have a dopant concentration of, for example, 2.0×10¹⁷/cm³ is grown by epitaxy to have a thickness of, for example, 1.3 μm.

By the processes up to here, the silicon carbide substrate in which the n⁻-type drift layer 2 and the p-type base layer 6 are sequentially stacked on the front surface of the n⁺-type starting substrate 1 is fabricated. Next, a process including: formation of an ion implantation mask by photolithography and etching, ion implantation using the ion implantation mask, and removal of the ion implantation mask, as one set is repeatedly performed under different ion implantation conditions, thereby forming in the p-type base layer 6, at the surface thereof, the n⁺⁺-type source regions 7 and the p⁺⁺-type contact regions 8. Preferably, a dopant concentration of the p⁺⁺-type contact regions 8 may be 1.0×10²⁰/cm³.

Further, in the transition region 41 and the termination structure region 42, the n⁺⁺-type source region 7 therein may be formed by ion implantation of an n-type dopant in a region beneath the source ring 25 without forming the p⁺⁺-type contact regions 8 in the region beneath the source ring 25. Therefore, the dopant concentration of the p⁺⁺-type contact regions 8 is higher than the dopant concentration of the n⁺⁺-type source regions 7 of the transition region 41 and the termination structure region 42.

Next, the guard ring structure 21 is selectively formed in the termination structure region 42 by photolithography and ion implantation. Next, the n⁺⁺-type region 23 is selectively formed in the termination structure region 42 by photolithography and ion implantation.

Next, a heat treatment (annealing) is performed thereby activating, for example, the first p⁺-type base regions 3, the n⁺⁺-type source regions 7, the p⁺⁺-type contact regions 8, the guard ring structure 21, and the n⁺⁺-type region 23. A temperature of the heat treatment may be, for example, about 1700 degrees C. A period of the heat treatment may be, for example, about 2 minutes. The ion implanted regions may be activated by a single session of the heat treatment as described or the heat treatment may be performed each time ion implantation is performed.

Next, an oxide film is formed on the surface the p-type base layer 6 (i.e., surfaces of the n⁺⁺-type source regions 7 and surfaces of the p⁺⁺-type contact regions 8). The oxide film may be, for example, a thermal oxide film or a deposited film. The oxide film is formed so that a portion of the oxide film in the active region 40 has a thickness that is thinner than a thickness of a portion of the oxide film formed along an outer periphery of the termination structure region 42.

Next, a resist mask (not depicted) having predetermined openings is formed by photolithography at the surface of the oxide film. Next, openings are formed in the oxide film by dry etching using the resist mask as a mask. Next, the resist mask is removed and the trenches 16 that penetrate through the n⁺⁺-type source regions 7 and the p-type base layer 6 and reach the n⁻-type drift layer 2 are formed by anisotropic dry etching using the oxide film as a mask. The bottoms of the trenches 16 reach the first p⁺-type base regions 3.

Next, isotropic etching and sacrificial oxidation are performed without removing the oxide film. This process removes damage of the trenches 16 and rounds the bottoms of the trenches 16. A sequence in which the isotropic etching and the sacrificial oxidation are performed is interchangeable. Further, either the isotropic etching or the sacrificial oxidation alone may be performed. Thereafter, the portion of the oxide film used as a mask to form the trenches 16 (the portion where the thickness is relatively thin) is removed. At this time, the portion of the oxide film where the thickness is relatively thin and the sacrificial oxide film may be removed concurrently. The oxide film includes the portion that is relatively thin and in the termination structure region 42, the portion that is relatively thick and thus, etching for removing the relatively thin portion of the oxide film is performed in an entire area of the surface, leaving the relatively thick portion of the oxide film in the termination structure region 4. The sacrificial oxide film (not depicted) may be removed together with the relatively thin portion of the oxide film. Further, the oxide film may be removed by photolithography and etching, leaving the oxide film in the termination structure region 42. The oxide film (the relatively thick portion of the oxide film) left in the termination structure region 42 constitutes the initial oxide film 17.

Next, the gate insulating film 9 is formed along surfaces of the initial oxide film 17, the n⁺⁺-type source regions 7, the p⁺⁺-type contact regions 8, and the bottoms and sidewalls of the trenches 16. The gate insulating film 9 may be formed by thermal oxidation of a temperature of about 1000 degrees C. under an atmosphere containing oxygen. Further, the gate insulating film 9 may be formed by a deposition method by a chemical reaction such as that for a high temperature oxide (HTO).

Next, a polycrystalline silicon layer doped with, for example, phosphorus atoms (P) is formed on the gate insulating film 9. The polycrystalline silicon layer is formed so as to be embedded in the trenches 16. The polycrystalline silicon layer is patterned and left inside the trenches 16, thereby forming the gate electrodes 10. A portion of each of the gate electrodes 10 may protrude from a top of each of the trenches 16 in a direction toward the source electrode 12.

Next, for example, a phosphosilicate glass (PSG) is deposited to a thickness of about 1 μm so as to cover the gate insulating film 9 and the gate electrodes 10, thereby forming the interlayer insulating film 11. The interlayer insulating film 11 and the gate insulating film 9 are patterned and selectively removed, thereby forming contact holes and exposing the n⁺⁺-type source regions 7 and the p⁺⁺-type contact regions 8. Thereafter, a heat treatment (reflow) is performed, thereby flattening the interlayer insulating film 11.

Next, a conductive film constituting the source electrode 12 is formed in the contact holes and on the interlayer insulating film 11. The conductive film is selectively removed and, for example, the source electrode 12 is left only in the contact holes. The source electrode 12 is formed so as to be in ohmic contact with the p⁺⁺-type contact regions 8 and the p-type base layer 6.

Next, for example, an aluminum film having a thickness of, for example, about 5 μm is formed by, for example, by a sputtering method, so as to cover the source electrode 12 and the interlayer insulating film 11. Thereafter, the aluminum film is selectively removed and left so as to cover the active region 40 and the transition region 41 of the device overall, thereby forming the gate ring 24, the source ring 25, a source electrode pad 26, and the gate electrode pad 27. Thereafter, as a surface passivation film, a protective film (not depicted) is formed by applying a polyimide, for example, by spin coating, patterning the polyimide using a lithographic method, and performing a heat treatment (curing) on the polyimide. The source electrode pad 26 may be a portion of the source electrode 12 opened (exposed) from the polyimide or may formed by depositing another metal such as nickel on the portion of the source electrode 12 opened (exposed) from the polyimide.

Next, the back electrode 13 constituted by, for example, a nickel (Ni) film, is formed at the back surface (the back surface of the n⁺-type starting substrate 1) of the silicon carbide substrate. Thereafter, for example, a heat treatment is performed at a temperature of about 970 degrees C., whereby the n⁺-type starting substrate 1 and the back electrode 13 become in ohmic contact with each other.

The back electrode 13, for example, may be a stacked film including, sequentially, a titanium (Ti) film, a nickel (Ni) film, and a gold (Au) film or may be a stacked film including a nickel (Ni) film, a titanium (Ti) film, a molybdenum (Mo) film, and a gold (Au) film. Thus, as described, the semiconductor device depicted in FIGS. 1 to 3 is completed.

As described, according to the first embodiment, beneath the source ring is one of the n⁺⁺-type source regions, whereby a flow of current from the p-type base layer to the source ring is enabled while a flow of current from the source ring to the p-type base layer is prevented. Thus, even when resistance increases due to increases in temperature during an IFSM test, a flow of current from the source ring to the p⁺⁺-type contact regions may be prevented, concentration of the current in the source ring connecting portion is prevented, and IFSM capability may be improved.

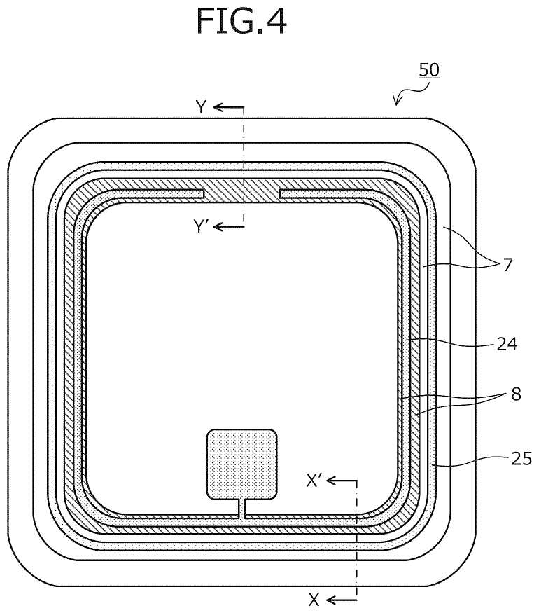

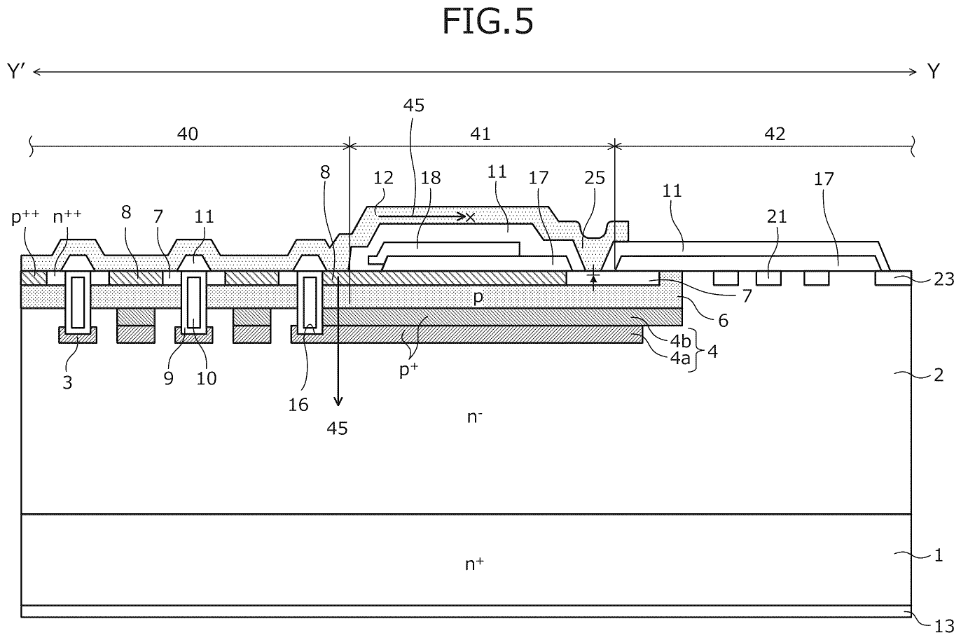

Next, a second embodiment is described. FIG. 4 is a plan view depicting the gate ring 24, the source ring 25, the p⁺⁺-type contact regions 8, and the n⁺⁺-type source regions 7 of a silicon carbide semiconductor device according to the second embodiment. FIG. 5 is a cross-sectional view depicting the structure of the silicon carbide semiconductor device according to the second embodiment along cutting line Y-Y′ depicted in FIG. 4. The structure above the n⁻-type drift layer 2 in the transition region 41 is the same as the structure depicted in FIG. 3 and the structure in the n⁻-type drift layer 2 in the transition region 41 is the same as the structure depicted in FIG. 5 and thus, a cross-sectional view along cutting line X-X′ depicted in FIG. 4 is omitted.

In the second embodiment, a width of the n⁺⁺-type source region 7 provided in the transition region 41 and the termination structure region 42 is narrower than the width thereof in the first embodiment while a width of the p⁺⁺-type contact region 8 in the transition region 41 is wider than the width thereof in the first embodiment. As depicted in FIG. 4, the p⁺⁺-type contact regions 8 are provided closer to the center of the active region 40 than is the source ring 25; the n⁺⁺-type source regions 7 are provided closer to the end of the n⁺-type starting substrate 1 than are the p⁺⁺-type contact regions 8; and the outermost one of the n⁺⁺-type source regions 7 is provided beneath the source ring 25.

Further, as depicted in FIG. 5, in the second embodiment, one of the p⁺⁺-type contact regions 8 is provided in the p-type base layer 6, at the surface thereof, extending from the outer sidewall of the outermost one of the trenches 16 into the transition region 41. The n⁺⁺-type source regions 7 are in contact with the p⁺⁺-type contact regions 8 and are provided to the termination structure region 42, the n⁺⁺-type source regions 7 being provided on sides of the p⁺⁺-type contact regions 8, said sides facing the end of the n⁺-type starting substrate 1. Thus, the source ring 25 is in contact with the outermost one of the n⁺⁺-type source regions 7 by an opening of the interlayer insulating film 11 and is not in contact with the p⁺⁺-type contact regions 8.

Further, the outermost one of the n⁺⁺-type source regions 7 is in the transition region 41 and the termination structure region 42 and may be formed by ion implantation of an n-type dopant in a region beneath the source ring 25 without forming the p⁺⁺-type contact regions 8 in the region beneath the source ring 25. Therefore, the dopant concentration of the p⁺⁺-type contact regions 8 is higher than the dopant concentration of the n⁺⁺-type source region 7 in the transition region 41 and the termination structure region 42.

In the second embodiment, similar to the first embodiment, a diode formed by the outermost one of the n⁺⁺-type source regions 7 and the p-type base layer 6 is formed beneath the source ring 25. As a result, effects similar to those of the first embodiment are achieved. In the second embodiment, the width of the outermost one of the n⁺⁺-type source regions 7 is narrower than the width thereof in the first embodiment and thus, Vf (forward voltage) may be reduced.

As described, according to the second embodiment, beneath the source ring is one of the n⁺⁺-type source regions and thus, effects similar to those of the first embodiment are obtained. In the second embodiment, the width of said n⁺⁺-type source region is narrower than the width thereof in the first embodiment and thus, Vf may be reduced.

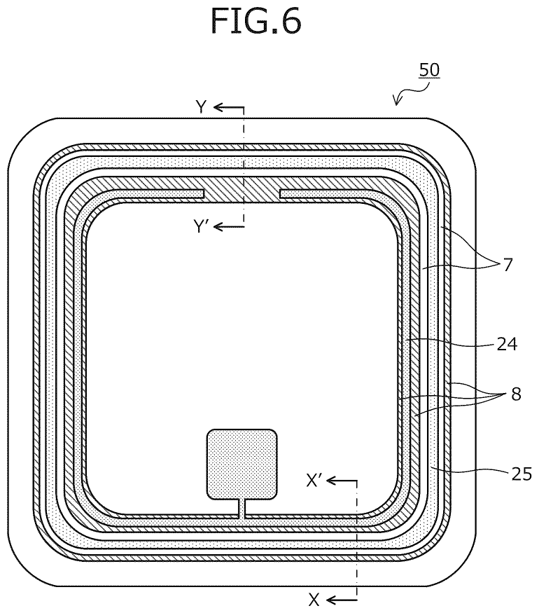

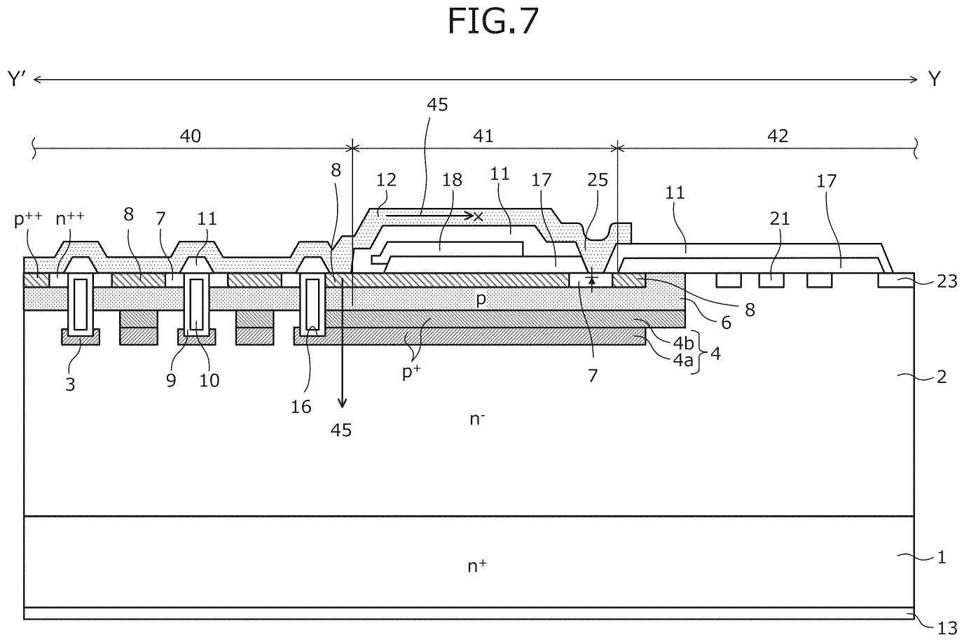

Next, a third embodiment is described. FIG. 6 is a plan view depicting the gate ring 24, the source ring 25, the p⁺⁺-type contact regions 8, and the n⁺⁺-type source regions 7 of the silicon carbide semiconductor device according to the third embodiment. FIG. 7 is a cross-sectional view depicting the structure of the silicon carbide semiconductor device according to the third embodiment along cutting line Y-Y′ depicted in FIG. 6. The structure above the n⁻-type drift layer 2 in the transition region 41 is the same as the structure depicted in FIG. 3 and the structure in the n⁻-type drift layer 2 in the transition region 41 is the same as the structure depicted in FIG. 7 and thus, a cross-sectional view along cutting line X-X′ depicted in FIG. 6 is omitted.

In the third embodiment, in the transition region 41, the width of the n⁺⁺-type source region 7 is narrower than the width thereof in the second embodiment while the width of one of the p⁺⁺-type contact regions 8 is wider. As depicted in FIG. 6, in the transition region 41, one of the p⁺⁺-type contact regions 8 is provided closer to the center of the active region 40 than is the source ring 25 while another one of the p⁺⁺-type contact regions 8 is provided closer to the end of the n⁺-type starting substrate 1 than is the source ring 25 and one of the n⁺⁺-type source regions 7 is provided therebetween, beneath the source ring 25.

Further, as depicted in FIG. 7, in the third embodiment, said one of the p⁺⁺-type contact regions 8 of the transition region 41 is provided from the outer sidewall of the outermost one of trenches 16 and terminates in the transition region 41 and the other one of the p⁺⁺-type contact regions 8 of the transition region 41 is provided in the p-type base layer 6, closer to the end of the n⁺-type starting substrate 1 than is the n⁺⁺-type source region 7 of the transition region 41. The n⁺⁺-type source region 7 of the transition region 41 is between and in contact with said p⁺⁺-type contact regions 8 of the transition region 41. The source ring 25 is in contact with the n⁺⁺-type source region 7 of the transition region 41 by an opening in the interlayer insulating film 11 and the source ring 25 is not in contact with the p⁺⁺-type contact regions 8.

Similar to the first embodiment, in the third embodiment, a diode formed by the n⁺⁺-type source region 7 of the transition region 41 and the p-type base layer 6 is formed beneath the source ring 25. As a result, effects similar to those of the first embodiment are obtained. In the third embodiment, the width of the n⁺⁺-type source region 7 of the transition region 41 is narrower than the width thereof in the second embodiment, whereby Vf (forward voltage) may be further reduced.

Further, the n⁺⁺-type source region 7 of the transition region 41 may be formed by implantation of an n-type dopant in a region beneath the source ring 25 without forming the p⁺⁺-type contact regions 8 in the region beneath the source ring 25 and therefore, the dopant concentration of the p⁺⁺-type contact regions 8 may be higher than the dopant concentration of the n⁺⁺-type source region 7 of the transition region 41.

As described, according to the third embodiment, beneath the source ring is one of the n⁺⁺-type source regions and thus, effects similar to those of the first embodiment are obtained. In the third embodiment, the width of the n⁺⁺-type source region of the transition region is narrower than the width thereof in the second embodiment, whereby Vf (forward voltage) may be further reduced.

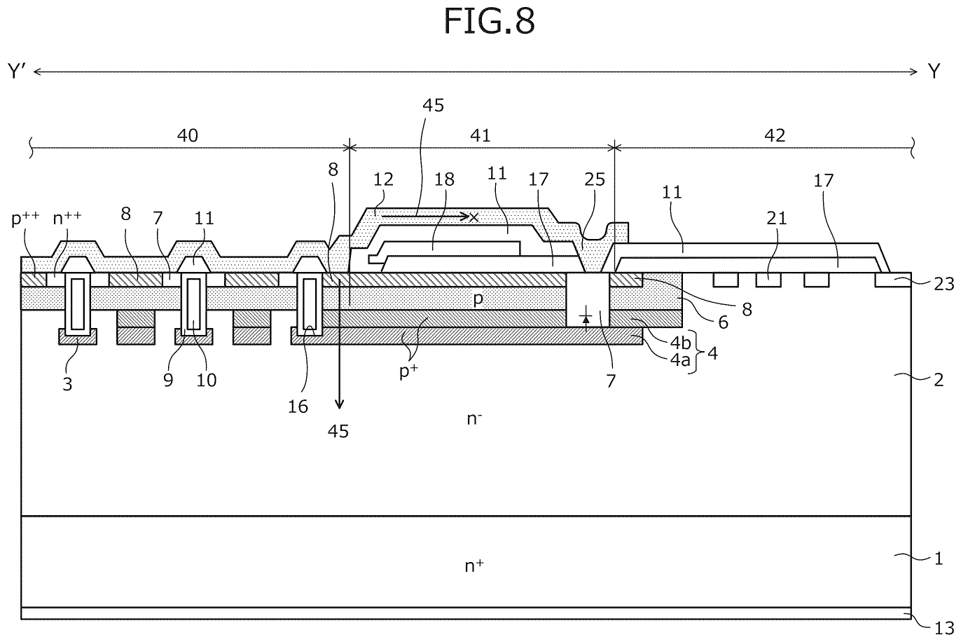

Next, a fourth embodiment is described. FIG. 8 is a cross-sectional view depicting the structure of a silicon carbide semiconductor device according to the fourth embodiment along cutting line Y-Y′ depicted in FIG. 6. A plan view of the fourth embodiment is a same as that depicted in FIG. 6 for the third embodiment and thus, is omitted. The structure above the n⁻-type drift layer 2 in the transition region 41 is the same as the structure depicted in FIG. 3 and the structure inside the n⁻-type drift layer 2 in the transition region 41 is the same as the structure depicted in FIG. 8 and thus, a cross-sectional view along cutting line X-X′ depicted in FIG. 6 is omitted.

In the fourth embodiment, in the transition region 41, the widths of the p⁺⁺-type contact regions 8 and the width of the n⁺⁺-type source region 7 are the same as the respective widths in the third embodiment, a depth (thickness) of the n⁺⁺-type source region 7 provided beneath the source ring 25 is greater than the depth thereof in the third embodiment. In the fourth embodiment, the n⁺⁺-type source region 7 provided beneath the source ring 25 is deeper than the p⁺⁺-type contact regions 8. For example, the n⁺⁺-type source region 7 provided beneath the source ring 25 penetrates through the p-type base layer 6 and the second p⁺-type region 4b to a depth reaching the surface of the first p⁺-type region 4a. Further, this deep n⁺⁺-type source region 7 may be formed by implanting an n-type dopant in the region beneath the source ring 25 without forming the p⁺⁺-type contact regions 8, the p-type base layer 6, or the second p⁺-type region 4b.

Similar to the first embodiment, in the fourth embodiment, a diode formed by the n⁺⁺-type source region 7 of the transition region 41 and the first p⁺-type region 4a of the transition region 41 is formed beneath the source ring 25. As a result, effects similar to those of the first embodiment are obtained. In the fourth embodiment, the depth of the n⁺⁺-type source region 7 of the transition region 41 is deeper than the depth thereof in the third embodiment, whereby the n⁺⁺-type source region 7 is in contact with the first p⁺-type region 4a of the transition region 41. Thus, a difference in n-type and p-type concentrations (dopant concentration of the n⁺⁺-type source region 7-dopant concentration of the first p⁺-type region 4a) of the fourth embodiment is smaller than a difference in the n-type and p-type concentrations (dopant concentration of the n⁺⁺-type source region 7-dopant concentration of the p-type base layer 6) of the first to third embodiments, whereby imbalance of the n-type and p-type concentrations during application of reverse bias may be suppressed.

As described, according to the fourth embodiment, beneath the source ring is one of the n⁺⁺-type source regions and thus, effects similar to those of the first embodiment are obtained. In the fourth embodiment, the depth of the n⁺⁺-type source region of the transition region is deeper than the depth thereof in the third embodiment, whereby the difference in n-type and p-type concentrations is reduced and imbalance of the n-type and p-type concentrations during application of reverse bias may be suppressed.

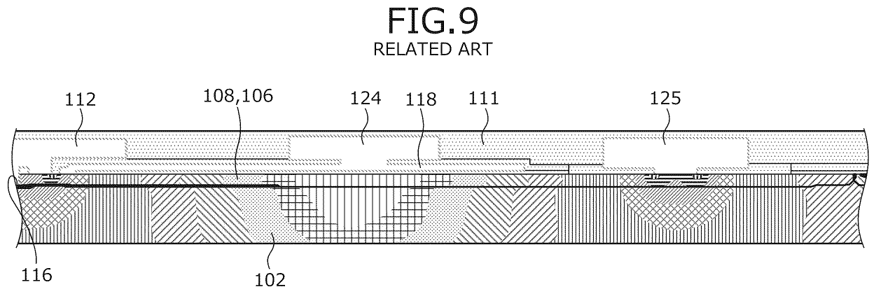

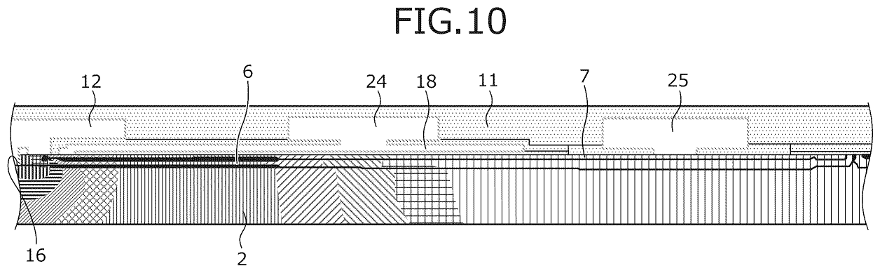

Effects of the disclosure are demonstrated by simulation. FIG. 9 is a cross-sectional view depicting current distribution of the conventional silicon carbide semiconductor device. FIG. 10 is a cross-sectional view depicting current distribution of the silicon carbide semiconductor device according to the first embodiment. FIGS. 9 and 10 show results of simulation of current distribution under conditions of Vgs=−3V, Is=500 A; regions with darker hatching have larger current values. In FIGS. 9 and 10, while not specified, the source rings 25, 125 are electrically connected to the source electrodes 12, 112, respectively.

As depicted in FIG. 9, in the conventional silicon carbide semiconductor device, current concentrates beneath the source ring 125 and the current values are large beneath the source ring 125. On the other hand, as depicted in FIG. 10, in the silicon carbide semiconductor device according to the first embodiment, concentration of current beneath the source ring 25 is suppressed and the current values are small. In the silicon carbide semiconductor device according to the first embodiment, while current concentrates beneath the source electrode 12 and the current values beneath the source electrode 12 are large, this is a result of simulation being performed with one opening of the source electrode 12 of the active region 40 and thus, current concentrated at the one source electrode 12. In an actual semiconductor device, the area of the source electrode 12 is large and there are multiple openings and thus, current does not concentrate at one opening and this state does not occur.

In the foregoing, while an instance in which MOS gate structures are configured at the first main surface of a silicon carbide substrate is described as an example, the present disclosure is not limited hereto and various modifications such as surface orientation of the substrate, etc. are possible. Further, in the embodiments of the present disclosure, while a trench-type MOSFET is described as an example, without limitation hereto, the present disclosure is applicable to various semiconductor devices of various types of configurations such as MOS semiconductor devices like trench-type IGBTs. Further, in the present disclosure, while the first conductivity type is assumed to be an n-type and the second conductivity type is assumed to be a p-type in the embodiments, the present disclosure is similarly implemented when the first conductivity type is a p-type and the second conductivity type is an n-type.

According to the disclosure described above, beneath the source ring is a second semiconductor region of the first conductivity type and thus, a flow of current from a plurality of first semiconductor regions of the second conductivity type to the source ring is enabled while a flow of current from the source ring to the plurality of first semiconductor regions may be prevented. Thus, even when resistance increases due to increases in temperature during an IFSM test, the flow of a current from the source ring to the plurality of first semiconductor regions may be prevented, concentration of the current in source ring connecting portion is prevented, and IFSM capability may be improved.

The semiconductor device according to the present disclosure achieves an effect in that concentration of current in the source ring portion is suppressed and IFSM capability is improved.

As described, the semiconductor device according to the present disclosure is useful for high-voltage semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having:
an active region through which a main current flows,
a termination region surrounding a periphery of the active region in a plan view of the semiconductor device, and
a transition region between the active region and the termination region;
a plurality of first semiconductor regions of a second conductivity type, formed in the semiconductor substrate;
a front electrode at a surface of the semiconductor substrate, in the active region, the front electrode being connected to the plurality of first semiconductor regions;
a source ring for pulling out a current, the source ring being electrically connected to the front electrode in the transition region, and having a side facing the semiconductor substrate; and
a second semiconductor region of the first conductivity type, formed in the semiconductor substrate at the side of the source ring, the source ring being connected to the second semiconductor region.

2. The semiconductor device according to claim 1, wherein
the second semiconductor region is one of a plurality of second semiconductor regions provided in the active region, the termination region, and the transition region, and
an entire area of the surface of the semiconductor substrate in the transition region has one of the plurality of second semiconductor regions provided therein.

3. The semiconductor device according to claim 1, wherein
the plurality of first semiconductor regions is provided in the termination region and the transition region,
the second semiconductor region is provided at the side of the source ring in the transition region, and
the second semiconductor region is one of a plurality of second semiconductor regions provided in the termination region and the transition region, the plurality of second semiconductor regions being in contact with the plurality of first semiconductor regions in the termination region and in the transition region.

4. The semiconductor device according to claim 1, wherein
the plurality of first semiconductor regions is provided in the active region, the termination region, and the transition region, and
the second semiconductor region is in contact with the plurality of first semiconductor regions in the transition region and is provided at the side of the source ring in the transition region.

5. The semiconductor device according to claim 4, further comprising a third semiconductor region of the second conductivity type, facing the plurality of first semiconductor regions in a depth direction, the third semiconductor region having a dopant concentration higher than a dopant concentration of the plurality of first semiconductor regions, wherein
the second semiconductor region is deeper than the plurality of first semiconductor regions and reaches the third semiconductor region in the depth direction.

6. The semiconductor device according to claim 1, wherein a dopant concentration of the plurality of first semiconductor regions is higher than a dopant concentration of the second semiconductor region.
